(19) United States
(12) Patent Application Publication
(10) Pub. No.: US 2021/0172208 A1
(43) Pub. Date: Jun. 10, 2021

(54) SENSOR LEVER FOR TECHNICAL APPLICATIONS IN MOTOR VEHICLES

(71) Applicant: Kiekert AG, Heiligenhaus (DE)

(72) Inventor: Bryan Bishop, Walled Lake, MI (US)

(21) Appl. No.: 16/702,642

(22) Filed: Dec. 4, 2019

(51) Int. Cl. E05B 79/08; E05B 79/16; B60W 50/16; E05B 39/00

(52) U.S. Cl. CPC E05B 79/08; E05B 79/16; E05B 81/68; E05B 39/007; B60W 50/16

(57) ABSTRACT

A sensor lever for technical applications in motor vehicles. In its basic configuration, this sensor lever has a base lever arm and a sensor lever arm for installing at least one sensor and/or a tactile element. According to the invention, the sensor lever arm is aligned in the desired position with respect to base lever arm in the course of production.

The invention concerns a sensor lever for technical applications in motor vehicles, with a base lever arm and a sensor lever arm for mounting at least one sensor and/or a tactile element.

Various forms of sensor levers are used for technical applications in motor vehicles and in quite different fields of application. It is, for example, possible to determine by means of such a sensor lever whether a fuel filler cap or a tailgate of a vehicle is locked or un-locked, as described in the generic patent DE 10 2011 116 068 A1. A detection device by means of which the opening state of the tank or tail gate is determined is, in fact, provided at this location. A switching device, which determines the position of a locking pin and/or a swing lever, serves, for example, as a sensor lever. It is also possible to fall back on a Hall sensor connected to a permanent magnet. The permanent magnet takes on the function of a tactile element in this case.

Other sensor levers for technical applications in motor vehicles serve the purpose of querying the functional position of a lock cylinder, as in the subject matter of DE 197 02 276 A1. A circular arc-shaped layered magnet segment, which can be rotated about a geometric axis of the lock cylinder and along with lock cylinder by means of a key, is provided as a tactile element. An additional Hall sensor can then capture and sense the respective assumed functional position of the lock cylinder.

The production of the sensor lever for technical applications in motor vehicles is basically subject to variances. Such sensor levers are, for example, actually made of plastic and are produced by injection molding. Contractions can consequently take place in the cooling process, which cause the sensor lever arm for mounting at least one sensor and/or one tactile element to to not maintain their previously fixed positions and/or variations with respect to a target position to be observed. In extreme cases, this can result in wrong sensor signals, which are, for example, misinterpreted by a control unit evaluating the sensor signals. It is here that the invention is intended to provide a remedy.

It is the technical object of the invention to further develop a sensor lever for technical applications in motor vehicles such that variations in the position of the tactile element or respectively the sensor attributable to manufacture and/or assembly are avoided if at all possible.

In the context of this invention, a generic sensor lever for technical applications in motor vehicles is characterized as a solution of this technical problem, in that the sensor lever arm is in the desired position with respect to the base lever arm and/or is aligned into the desired position during production.

The invention thus proceeds so that the tactile element, respectively the sensor lever arm carrying the sensor, can be simultaneously displaced into a desired position and aligned in this position during the production process. In doing so the invention first proceeds from the perception that such a sensor lever is typically produced via a molding process wherein an initially liquid material is molded and then cooled. The molding process in question can generally be a metal casting process and/or a metal injection process. But, according to an advantageous embodiment, the sensor lever is made of a synthetic material, so that a plastic injection molding process is typically used and considered as the molding process.

According to the invention, this molding process in general and the plastic injection molding process in particular is now operated in a way such that the sensor lever arm is in a desired position, while the material and/or substance being used is still capable of flowing. To accomplish this, an injection mold can, for example, be equipped with one or more movable dies or extrusion dies, which are, in turn, traversed during the production process. Such an approach, to which DD 41,656 only refers as an example, has been known widely and for a long time. Assuming that the sensor lever arm is configured for mounting at least the sensor and/or the tactile element by means of one or more traversable dies within the plastic injection mold, it is immediately apparent that the position of the sensor lever with respect to the base lever can be changed via an appropriate activation of the one or more dies.

In fact, one then mostly proceeds in a manner such that the sensor lever arm largely extends at an angle, particularly at a right angle, to the base lever. In addition, the sensor lever arm mostly has a receptacle for the sensor and/or the tactile element. In doing this, one regularly proceeds in such a way that the receptacle is aligned in the desired direction in the course of production.

As applied to an actual individual case, this means that the uptake of the sensor lever arm regarding its position with respect to the base lever arm can be altered by means of the one or more dies inside the plastic injection mold. In this case, one will typically proceed in such a way that the center of the receptacle is aligned with respect to the axis of rotation of the base lever. If the receptacle is circular, the center is defined by an associated center axis, which in turn extends mostly parallel to the axis of rotation of the base lever. As the one or more displaceable dies, which define the sensor lever arm generally and the receptacle concretely, is/are then moved in the molding tool and/or the plastic injection mold, it is also possible to change the position of the receptacle and consequently of the center axis with respect to the axis of rotation. For example, it is possible to change the axial distance between the center axis and the axis of rotation. The invention also offers the possibility of changing the radial position of the center axis of the receptacle with respect to the axis of rotation. Combinations are also conceivable and are included.

The orientation of the receptacle with respect to the sensor lever arm and typically with respect to its axis of rotation as a quasi-fixed point can then take place based on empirical values. For example, if the shrinkage and the cooling behavior of the sensor lever are collectively known, and therefore also any displacements of the receptacle and/or its center axis with respect to the axis of rotation of the base lever, it is possible to take such a shift caused by cooling into account by holding the receptacle along with its center axis, as it were, “in reserve” when considering the expected displacement caused by the cooling process. It is thus fully expected that, after the cooling process, the receptacle, along with its center axis, will be in the ready-to-install state, in its exact and specified position with respect to the axis of rotation.

Aside from such variations of the sensor lever due to production and therefore also variations in the position of the receptacle, it is also possible, according to this invention, to make up for variations attributable to installation and assembly. In this case, the alignment and possibly the shift of the sensor lever arm and/or the receptacle with respect to the base lever takes account of the subsequent location of installation and of any displacements or variations with respect to the base lever encountered there. This is also possible according to the invention. In doing so, the displacement of the receptacle observed in the course of the installation is determined in a way that is comparable with that observed in the cooling process. According to the invention, the actual production process of the sensor lever can then be run in such a way that account is taken of the expected displacement of the receptacle in the production process by again equipping the receptacle with a “leader”.

All of this can be illustrated simply in terms of control technology, in that the respectively zo expected deviation (attributable to production and assembly) is first determined empirically. This can correspond to a deviating position of the receptacle and/or the center axis with respect to the axis of rotation assumed in the course of production and/or assembly. This deviating position corresponds to a certain axial distance of the center axis to the axis of rotation and/or to an initially empirically determined radial position. Both obtained values (deviating position) can then be received by, e.g., a control unit driving the molding tool and/or the plastic injection mold and can be taken into consideration in the production process, so that the receptacle and its center axis is displaced far enough with respect to the axis of rotation of the sensor lever and/or its sensor lever arm for the receptacle to be in its predetermined position (setpoint position) after production and subsequent to the cooling process.

In this way, it is, e.g., possible to place a permanent magnet in the receptacle and it can be readily detected and evaluated by an opposite sensor and/or Hall sensor. No (more) false signals are to be expected according to the invention. This can alternatively be a tactile element or an optical surface structured in a certain way, which is also sensed in a contactless way by an optical sensor. A path sensor, a resistance sensor or other designs recording the path of the sensor lever are also conceivable in this context and are covered by the invention.

A sensor lever is consequently made available, which offers a maximum degree of precision in evaluating sensor signals for motor vehicle technical applications along with simple and economical production. This can be attributed to the fact that any production and/or assembly-related deviations from a previously established target position are taken into account and an appropriate compensation is provided. All of this succeeds by allowing for a simple and economical production process, without having to take and apply expensive precision actions. The object of this invention is a process for producing such a sensor lever, which is also described in greater detail in the claims 8 to 10.

The invention is hereinafter explained in greater detail by means of a drawing showing a single exemplary embodiment which describes:

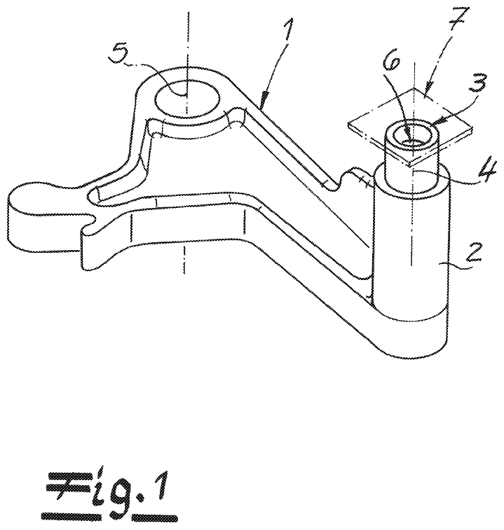

FIG. 1 The sensor lever according to the invention for technical applications in a motor vehicle in typical mounting conditions and

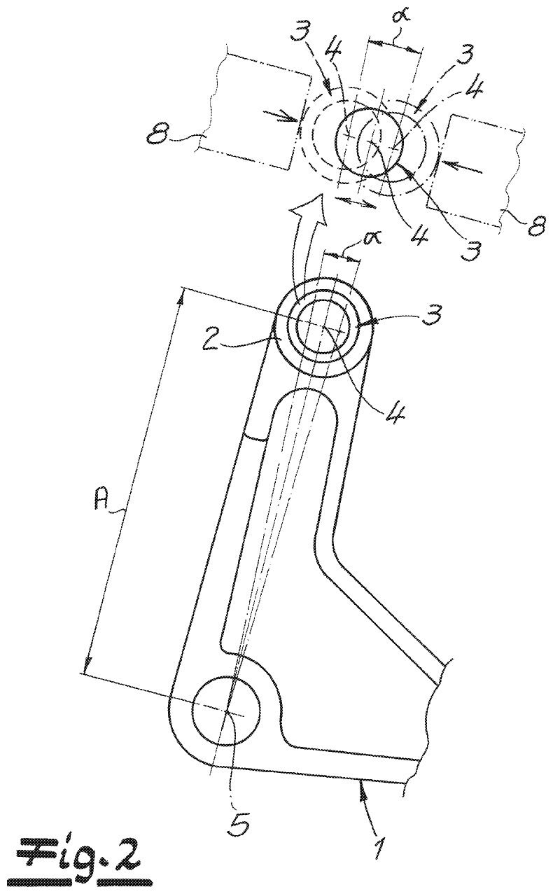

FIG. 2 the sensor lever within the region of the sensor lever arm with different suggested positions of the receptacle.

The figures show a sensor lever for technical applications in motor vehicles. In its basic configuration, the sensor lever has a base lever arm 1 and a sensor lever arm 2. It is evident that the sensor lever arm 2 largely extends at an angle and, according the exemplary embodiment, mostly at a right angle with respect to the base lever arm 1. The sensor lever arm 2 is in addition equipped with a receptacle 3. The receptacle 3 in the exemplary embodiment is nonrestrictively a circular receptacle 3 in the form of a hollow cylinder. The receptacle 3 in question thus defines a center axis 4, which acts as a rotational symmetry axis for the mounting 3. It is evident from the exemplary embodiment that the center axis 4 in question extends parallel to an axis of rotation 5 of the sensor lever.

The sensor lever can now perform swiveling movements around its axis of rotation 5. According to the exemplary embodiment, a permanent magnet 6 is located inside the receptacle 3, acting as tactile element 6, whose position is sensed by means of a sensor 7, which is immovably positioned at a short distance above the sensor. According to the exemplary embodiment, the sensor 7 is a Hall sensor.

It is, among other things, possible to determine in this way by means of the sensor lever whether a tank or filling flap is locked or unlocked as described in the generic patent DE 10 2011 116 068 A1. It is also alternatively or additionally possible to determine the positions of a lock cylinder with the assistance of the sensor lever, as the previously cited patent DE 197 02 276 A1 teaches in detail. The sensor lever in question can, in principle, also be used for other positioning movements and their detection, for example for determining the state of closure of a locking mechanism on the inside of a motor vehicle lock. The sensor lever can also, for example, be used to determine the position of a motor vehicle door, a motor vehicle window with an electrical window lifter, etc., to just name a few individual examples, which are under no circumstances to be understood as restrictive or conclusive.

According to the invention, the possibility now exists for the sensor lever arm 2 and the receptacle 3 for the permanent magnet 6 to be aligned in a desired position in the course of the production of the sensor lever. According to the exemplary embodiment, the sensor lever is a plastic lever. The sensor lever is accordingly produced by means of a plastic injection mold.

The plastic injection mold has one or more dies 8, which are suggested schematically in the top view according to FIG. 2 and can be displaced in the direction suggested by a double arrow. A control unit, which is not represented, takes care of this. The displaceability of the single or several dies 8 has the consequence that the center axis 4 of the receptacle 3 alters its position with respect to the axis of rotation 5. This position of the center axis 4 with respect the axis of rotation 5 can actually cause a variation such that an axial spacing A of the center axis 4 with respect to the axis of rotation 5 changes, as suggested in FIG. 2. It is also alternatively or additionally possible for the center axis 4 to vary its radial position with respect to the axis of rotation 5, which is shown by means of a suitable swivel angle a in the representation according to FIG. 2. It is basically also naturally possible for the center axis 4 to alter both its radial and its axial position with respect to the axis of rotation 5 in the described production process.

In this way, the injection mold and/or one or both dies 8 can be actuated by means of the not shown control unit in such a way that the center axis 4 of the receptacle 3 assumes a certain predetermined defined position and/or setpoint position after the production process and possibly after the installation of the sensor lever.

This position is usually prespecified by the stationary sensor and/or the Hall sensor 7. I.e., according to the exemplary embodiment, one will encounter a configuration such that, in the course of the production process, the center axis 4 is positioned with respect to the axis of rotation 5 in such a way that the permanent magnet 6 located inside the receptacle 3 is centered with respect to the fixed sensor 7 and/or the Hall sensor 7. The thereby defined zero-position and/or setpoint position of the sensor lever can now always be reproducibly set according to this invention, with any manufacturing tolerances. As a consequence of this, every swivel motion of the sensor lever and therefore any movement of the permanent magnet 6 with respect to the stationary sensor and/or Hall sensor 7 corresponds to the fact that a sensor signal accurately reproducing the movement is supplied by the sensor and/or Hall sensor 7. Incorrect signals are no longer observed.

FIG. 2 shows the target position of the center axis 4 drawn through after the production and the installation of the sensor lever. In order to achieve the drawn through position, the center axis is transposed into the position shown dashed or dotted during production. After the cooling of the sensor lever and its installation, the center axis 4 is in its setpoint position shown drawn with continuous lines.

### REFERENCE SYMBOL LIST

1 Base lever arm

2 Sensor lever arm

3 Receptacle

4 Center axis

5 Axis of rotation

6 Permanent magnet, tactile element

7 Sensor and/or Hall sensor

8 Die

A Axial separation

α Swivel angle

1. A sensor lever for technical applications in motor vehicles, the sensor lever comprising:
a base lever arm; and
a sensor lever arm for mounting at least one sensor and/or a tactile element, wherein the sensor lever arm is oriented in a predetermined position with respect to the base lever arm during manufacturing of the sensor lever.

2. The sensor lever according to claim 1, wherein the sensor lever arm extends at an angle with respect to the base lever arm.

3. The sensor lever according to claim 2, wherein the sensor lever arm extends at a right angle to the base lever arm.

4. The sensor lever according to claim 1, wherein the sensor lever arm has a receptacle for the sensor and/or the tactile element.

5. The sensor lever according to claim 4, wherein the receptacle is aligned in the predetermined position during manufacturing of the sensor lever.

6. The sensor lever according to claim 4, wherein a center of the receptacle is oriented with respect to an axis of rotation of the base lever arm.

7. The sensor lever according to claim 6, wherein the receptacle is circular, with a center axis running parallel to the axis of rotation of the base lever arm.

8. A method for producing a sensor lever for technical applications in motor vehicles, with a base lever arm and a sensor lever arm for mounting at least one sensor and/or a tactile element, the method comprising:
aligning the sensor lever arm in a predetermined position with respect to base lever arm during manufacturing of the sensor lever, wherein the sensor lever arm is oriented in the predetermined position with respect to the base lever arm after the manufacturing of the sensor lever.

9. The method according to claim 8 further comprising forming the sensor lever of plastic.

10. The method according to claim 8 further comprising aligning the sensor lever arm with respect to the base lever arm during an injection molding process.

11. The method according to claim 8 further comprising actuating injection mold dies whereby a center axis of a receptacle of the sensor lever arm assumes a predetermined position.

12. The method according to claim 11 further comprising positioning the center axis of the receptacle relative to an axis of rotation of the sensor lever.

13. The method according to claim 12 further comprising inserting a permanent magnet in the receptacle whereby the permanent magnet is centered relative to the at least one sensor which is stationary.

14. The sensor lever according to claim 1 further comprising a magnet that is the tactile element and is arranged in a receptacle of the sensor lever arm.

15. The sensor lever according to claim 14, wherein the magnet is moved with the sensor lever, and wherein the magnet is centered relative to the at least one sensor which is stationary.

16. The sensor lever according to claim 1, wherein the at least one sensor is a Hall sensor.

17. The sensor lever according to claim 1, wherein the sensor lever is formed of a plastic material.

18. The sensor lever according to claim 1, wherein the sensor lever is injection molded.
